(19) United States
(12) Patent Application Publication
(10) Pub. No.: US 2010/0034010 A1
(43) Pub. Date: Feb. 11, 2010

(54) MEMORY DEVICES WITH CONCENTRATED ELECTRICAL FIELDS

(75) Inventors: Haiwen Xi, Prior Lake, MN (US); Zheng Gao, Savage, MN (US); Song S. Xue, Edina, MN (US)

Correspondence Address: INTELLECTUAL PROPERTY GROUP;SEAGATE TECHNOLOGY FILES, FREDRIKSON & BYRON, PA, 200 SOUTH SIXTH ST, SUITE 4000, MINNEAPOLIS, MN, 55402-1425, US

(73) Assignee: Seagate Technology LLC, Scotts Valley, CA (US)

(21) Appl. No.: 12/329,150

(22) Filed: Dec. 5, 2008

Related U.S. Application Data
(60) Provisional application No. 61/086,481, filed on Aug. 6, 2008.

(51) Int. Cl. G11C 11/00

(52) U.S. Cl. 365/148

(57) ABSTRACT

Designs of resistance memory and phase change memory devices with memory cells having metallic inclusion at least in the area of electrode/medium layer interfaces. Such metallic inclusion is used to concentrate electric fields during writing. Consequently, resistance switching for the devices primarily occurs in the area of the metallic inclusion. As a result, better control of the resistance switching can be attained, thereby optimizing performance of the memory devices.

### PRIORITY CLAIM

The present application claims priority to U.S. Provisional Application Ser. No. 61/086,481, filed on Aug. 6, 2008, which is incorporated by reference herein in its entirety.

### BACKGROUND

Memory with high density and speed, low power consumption, small form factor, and low cost has been in high demand.

Memory can either be classified as volatile or non-volatile. Volatile memory is memory that loses its contents when the power is turned off. In contrast, non-volatile memory does not require a continuous power supply to retain information. Many non-volatile memories use solid-state memory devices as memory elements. In some cases, nonvolatile memory devices have employed flash memory. In general, such a flash memory device includes memory cells, each of which has a stacked gate structure.

In recent years, non-volatile memory devices designs have employed resistive random access memory (RRAM). A unit cell of the RRAM includes a data storage element which has two electrodes and a variable resistive material layer interposed between the two electrodes. The variable resistance layer, i.e., the data storage material layer, has a reversible variation in resistance according to the polarity and/or magnitude of an electric signal (voltage or current) applied between the electrodes. Such reversible resistance variation is often referred to as the electrical pulse induced resistance (EPIR) effect, and has enabled RRAM to be a promising solution over conventional memory such as flash memory (as briefly described above) as well as other known memory schemes, such ferroelectric random access memory (FRAM), magnetoresistive random access memory (MRAM), and the like.

Unfortunately, limitations have been noted with respect to RRAM devices. For example, write power for RRAM is generally considered to be too high, and the write pulse duration is also generally considered to be too long. In addition, overall data retention and resistance variation at either high or low states have been found to be challenging for RRAM. Embodiments of the present invention are focused on addressing these limitations of RRAM.

### SUMMARY

Embodiments of the invention are related to designs of resistance memory and phase change memory devices. The devices are provided with memory cells having metallic inclusion at least in the area of electrode/medium layer interfaces. Such metallic inclusion can be used to concentrate electric fields during writing. Consequently, resistance switching for the devices primarily occurs in the area of the metallic inclusion. As a result, better control of the resistance switching can be attained, thereby optimizing the memory devices to achieve lower applied pulse power, faster write speed, more stable resistance switching, better data retention and resistance variation when compared to conventional non-volatile devices.

In certain embodiments, a non-volatile memory cell is provided. The non-volatile memory cell includes a first electrode and a second electrode electrically connected by a medium layer. The medium layer is formed of one or more of insulating material and semi-conductive material. At least one of the first electrode and the second electrode has one or more metallic inclusions distributed thereon. The one or more metallic inclusions extend from the at least one first electrode and second electrode into the medium layer.

In certain embodiments, a non-volatile memory array is provided. The non-volatile memory array includes a plurality of conductive lines and a layer of memory cells. The conductive lines form an upper layer and a lower layer. The conductive lines of the upper layer cross over the conductive lines of the lower layer such that a plurality of cross points is formed there between. Each memory cell includes a medium layer electrically connecting one of the conductive lines of the upper layer with one of the conductive lines of the lower layer at one of the cross points. The medium layer of each memory cell is formed of one or more of insulating material and semi-conductive material. One or both of the conductive lines of the upper layer and the conductive lines of the lower layer have one or more metallic inclusions distributed thereon. The one or more metallic inclusions extend from the one or both upper layer conductive lines and lower layer conductive lines into the medium layers of the memory cells.

These and various other features and advantages will be apparent from a reading of the following detailed description.

### BRIEF DESCRIPTION OF THE DRAWINGS

FIG. 1A depicts, in perspective view, an exemplary cross point memory array employing a single layer of memory in accordance with certain embodiments of the present invention.

FIG. 1B depicts, in perspective view, an exemplary stacked cross point memory array employing two layers of memory in accordance with certain embodiments of the present invention.

FIGS. 2A and 2B are, respectively, a depiction in elevation view of a basic electrical circuit diagram including a two terminal memory cell, and a plot demonstrating current-voltage characteristic of the memory cell of FIG. 2A.

FIGS. 3A and 3B depict elevation views of an exemplary memory cell in accordance with certain embodiments of the present invention.

FIG. 4 depicts an elevation view of another exemplary memory cell in accordance with certain embodiments of the present invention.

FIGS. 5A and 5B depict elevation views of further exemplary memory cells in accordance with certain embodiments of the present invention.

### DETAILED DESCRIPTION OF THE PREFERRED EMBODIMENTS

The following detailed description should be read with reference to the drawings, in which like elements in different drawings are numbered identically. Embodiments shown in the drawings are not necessarily to scale, unless otherwise noted. It will be understood that embodiments shown in the drawings and described herein are merely for illustrative purposes and are not intended to limit the invention to any embodiment. On the contrary, it is intended to cover alternatives, modifications, and equivalents as may be included within the scope of the invention as defined by the appended claims.

While embodiments of the invention are described herein with respect to non-volatile memory cells for RRAM, the invention should not be so limited. For example, phase change random access memory (PCRAM) would be understood by the skilled artisan to be related to the herein-described RRAM embodiments, as the write operation for PCRAM is related to RRAM both in terms of pulse length and pulse height. As such, while PCRAM, magnetic RAM (MRAM), and other like memories are not specifically detailed herein, their applicability to the embodiments described herein should be appreciated as they realize benefits from the disclosed structures of the present invention.

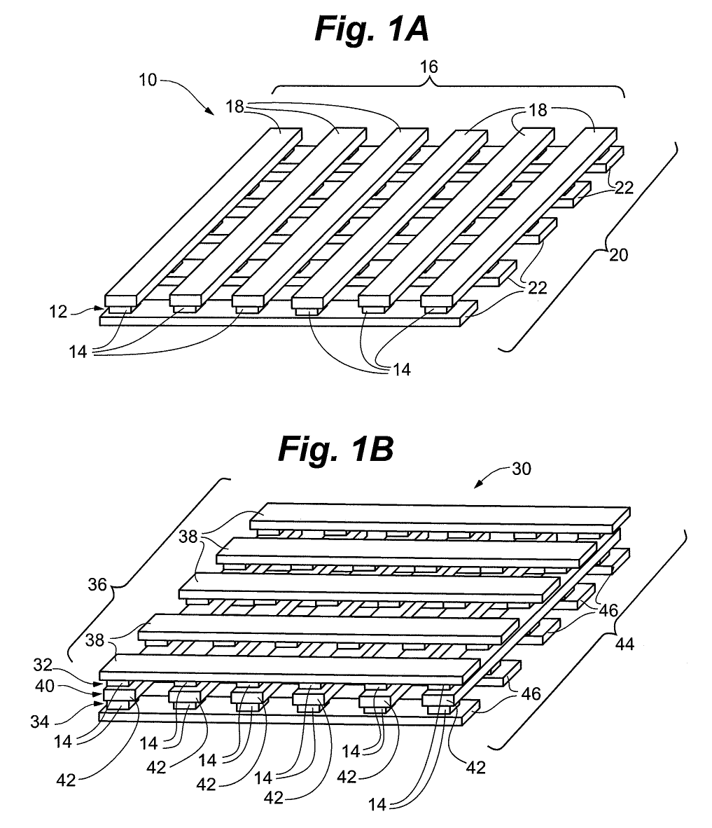

FIGS. 1A and 1B depict perspective views of an exemplary cross-point memory array 10 and an exemplary stacked cross-point memory array 30, respectively, in accordance with certain embodiments of the invention. Accordingly, the cross-point memory arrays 10, 30 represent memory structures, which can incorporate the memory cells embodied herein. In certain embodiments, the cross-point memory arrays 10 and 30 form resistance random access memory (RRAM).

A structural benefit of using cross-point memory array 10 (exemplary depicted in FIG. 1A) and the stacked cross-point memory array 30 (exemplary depicted in FIG. 1B) is that the active circuitry (not shown) which drives the array 10 or 30 can be placed beneath the array, therefore reducing the footprint required on a semiconductor substrate. However, embodiments of the invention should not be limited to only cross-point arrays, as other types of memory arrays can be used with a two-terminal memory element. For example, a two-dimensional transistor memory array can incorporate a two-terminal memory element. While the memory element in such an array would be a two-terminal device, the entire memory cell would be a three-terminal device.

As shown, the cross-point memory array 10 of FIG. 1 employs a single layer 12 of memory cells 14. The single memory layer 12 is sandwiched between a top layer 16 of conductive array lines 18 and a bottom layer 20 of conductive array lines 22. In certain embodiments, as shown, the conductive array lines 18 of the top layer 16 and the conductive array lines 22 of the bottom layer 20 are positioned orthogonal to each other (e.g., the conductive array lines 18 oriented in the x-direction and the conductive array lines 22 oriented in the y-direction). At each of the cross points between the array lines 18 and 22, one of the memory cells 14 is provided. In certain embodiments, for each of the memory cells 14, one of the conductive array lines 18 of the top layer 16 acts as a first terminal or electrode, and one of the conductive array lines 22 acts as a second terminal or electrode. The conductive array lines 18 and 22 are used to both supply voltage to, and carry current through, the memory cells 14 in order to determine their corresponding resistive states. In certain embodiments, a select device such as a diode or transistor is included with the memory cells 14 at each of the cross points between the array lines 18 and 22 to control the current path throughout the cross-point memory array 10. In certain embodiments, such select devices are connected in series with the memory cells 14 at the cross points.

The conductive array lines 18 and 22 of the top layer 16 and the bottom layer 20, respectively, can generally be constructed of any conductive material, such as Al, Cu, Pt, Ag, Au, Ru, W, Ti, TiN, other like materials, and certain conductive metal oxides such as SrRuO₃. Depending upon the material, a conductive array line would typically cross between 64 and 8192 perpendicular conductive array lines. Fabrication techniques, feature size and resistivity of material may allow for shorter or longer lines. Although the conductive array lines 18, 22 can be of equal lengths (forming a square cross point array), they can also be of unequal lengths (forming a rectangular cross point array), which may be useful if they are made from different materials with different resistivity.

The stacked cross-point memory array 30 of FIG. 1B employs two memory layers 32 and 34, each having memory cells 14′. It should be appreciated that the memory cells 14′ are generally similar in structure and function to the memory cells 14 of the array 10 of FIG. 1A. The memory layers 32, 34 are sandwiched between alternating layers of conductive array lines. As shown, the memory layer 32 is positioned between layer 36 of conductive array lines 38 and layer 40 of conductive array lines 42, while the memory layer 34 is positioned between the layer 40 of conductive array lines 42 and layer 44 of conductive array lines 46. Similar to that described above regarding the memory array 10 of FIG. 1, in certain embodiments, the conductive array lines connecting each of the memory layers are positioned orthogonal to each other (e.g., the conductive array lines 38 and 46 oriented in the x-direction and the conductive array lines 42 oriented in the y-direction). Accordingly, as shown, the conductive array lines 38 are orthogonal to the conductive array lines 42, and the conductive array lines 42 are orthogonal to the conductive array lines 46. At each of the cross points between the array lines 38 and 42, and between the array lines 42 and 46, one of the memory cells 14′ is provided. Similar to the memory array 10 of FIG. 1, in certain embodiments, a select device such as a diode or transistor is included with the memory cells 14′ at each of the cross points between the array lines 38 and 42 and/or 42 and 46 to control the current path throughout the stacked cross-point memory array 30. In certain embodiments, such select devices are connected in series with the memory cells 14′ at the cross points.

The conductive array lines 38, 42, and 46 of the array 30 can be generally formed and used as already described above with respect to the conductive array lines 18 and 22 of FIG. 1. However, while the conductive array lines 38 and conductive array lines 46 are used to supply voltage to, and carry current through, the memory cells 14′ of the memory layers 32 and 34, respectively, the other conductive array line layer 46 is doubly used to supply voltage to, and carry current through, the memory cells 14′ of both the memory layers 32 and 34. In turn, the resistive states of the memory cells 14′ of such memory layers 32 and 34 can be determined.

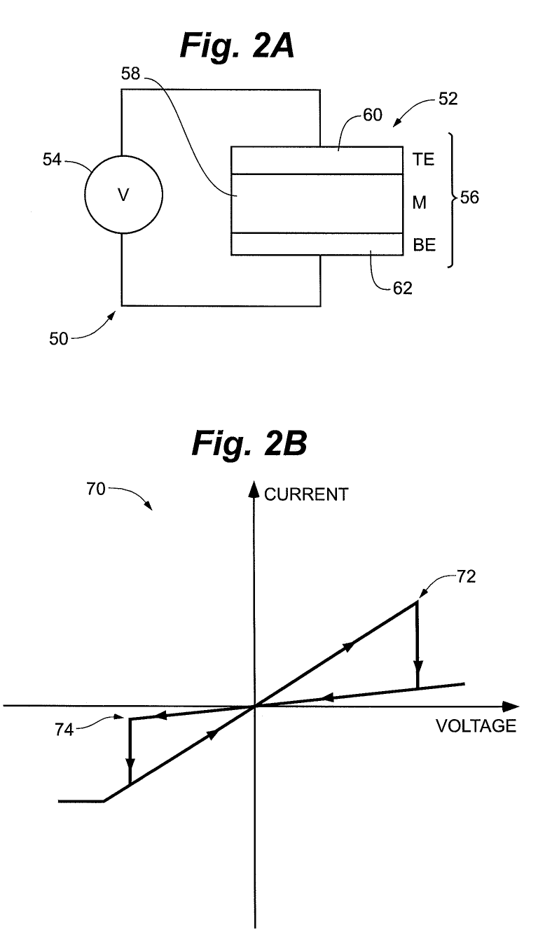

With reference to FIG. 1A, the point of intersection between any single conductive array line 18 and any single conductive array line 22 of the memory array 10 uniquely identifies one of the memory cells 14. Likewise, the point of intersection between any single conductive line 38 and any single conductive line 42, or any single conductive line 42 and any single conductive line 46, of the memory array 30 of FIG. 2 uniquely identifies one of the memory cells 14′. As should be appreciated, the memory cells 14 or 14′ are repeatable units that can be extended in one or two dimensions (e.g., with the memory array 10 of FIG. 1A, in which the cells 14 are repeated in both x- and y-directions) or even three dimensions (e.g., with the memory array 30 of FIG. 1B, in which the cells 14 are repeated in x-, y-, and z-directions). With continued reference to the array 30 of FIG. 1B, one method of repeating the memory cells in the z-direction (orthogonal to the x-y-planes) is to use both the bottom and top surfaces of doubly-used conductive array lines (e.g., lines 42), thereby creating a stacked cross-point array.

As described above, FIGS. 1A and 1B serve as examples of memory structures for the memory cells embodied herein. However, to fully illustrate the functioning of the embodied memory cells, it is best to understand their conventional construction and functioning, as briefly described above and further detailed below with respect to FIGS. 2A and 2B.

FIG. 2A depicts, in elevation view, an exemplary electrical circuit 50 including a two terminal memory cell 52 and a voltage source 54. The memory cell 52 includes a junction 56 formed of a medium layer 58 (referenced as M) sandwiched by two metallic electrodes, a top electrode 60 (referenced as TE) and a bottom electrode 62 (referenced as BE). The memory cell 52 is parsed from a RRAM device (e.g., from one of the memory arrays 10 or 30 of FIGS. 1A and 1B, respectively). Accordingly, its medium layer 58 is formed of a variable resistance material.

Memory cells for RRAM utilize the electrical pulse induced resistance (EPIR) effect, which refers to the phenomenon that an electrical pulse through the junction 56 of the memory cell 52 changes the resistance of the junction 56 from a low value to a high value. With reference to the electrical circuit 50, such electrical pulse is introduced to the memory cell 52 via the voltage source 54. In turn, an electrical pulse opposite to the aforementioned pulse can be introduced to reset the resistance of the junction 56 back from the high value to the low value. In certain embodiments, regarding the variable resistance materials of the medium layer 58, reset and set operations are conducted by the voltage pulses with the same polarity. In general, pulse height and/or pulse width may differ between the set and reset operations. As embodied herein, we use the bipolar mode to illustrate the EPIR effect.

Such above-described relationship is illustrated in FIG. 2B, showing a curve 70 demonstrating current-voltage characteristic of the memory cell 52 of FIG. 2A. In particular, the curve 70 generally shows the hysteretic and reversible resistance change characteristics for a TE/M/BE junction in RRAM due to the EPIR effect. For example, with reference to FIG. 2A, if the electrical pulse (current or voltage) of requisite magnitude 72 is delivered to the junction 56 of the memory cell 52, then the resistivity of the junction 56 increases sharply to a high value (with slope of the curve 70 being flattened). In turn, if a subsequent electrical pulse (current or voltage) of opposite magnitude 74 is delivered to the junction 56, than the resistivity of the junction 56 reverts back to a low value (with slope of the curve 70 being raised). The first change in characteristic is generally referenced as the reset process, while the second change in characteristic is generally referenced as the set process.

With reference to the junction 56 of the RRAM memory cell 50 shown in FIG. 2A, one can appreciate the limitations (e.g., high write power, long write pulse duration, and data retention challenges) that have been found to date. As illustrated, the contacting surfaces between the medium layer 58 and the electrodes 60, 62 are each generally planar with respect to each other.

Consequently, while a voltage provided across the junction 56 induces a current to flow from one of the electrodes 60 or 62 to the other electrode, there is a certain lack of control with respect to the path of the current as it flows through the medium layer 58. This lack of control directly impacts corresponding RRAM writing operations, the parameters associated therewith, and the resistance of the memory cell after the set and reset processes.

The writing power, for example, consequently needs to be high enough so as to sufficiently induce a strong electric field across the medium layer 58. In turn, the strength of the induced electric field enables current to uniformly conduct from the surface of the corresponding electrode 60 or 62, through the medium layer 58, to the surface of the other electrode. Such uniform conduction across the medium layer 58 is often considered excessive, and unduly necessitates high writing power. However, in such structures, without supplying such high writing power, the induced electric fields may not be uniformly created across the medium layer 58, which in turn, could adversely impact the writing process.

In addition, because the current must flow entirely through the medium layer 58, there is potential for the current to be undesirably delayed as it flows from one of the electrodes, 60 or 62, to the other electrode. Contributing to this delay is the manner in which the electrodes 60 and 62 are provided on the opposing sides of the medium layer 58. As described above, the contacting surfaces between the medium layer 58 and the electrodes 60 and 62 are each generally planar with respect to each other. Accordingly, there are many paths over which current flowing from one of the electrodes 60 or 62, through the medium layer 58, and to the other electrode can take. As a result, the duration for the average write pulse is found to be longer than desired.

Further, as described above, an electric field needs to be maintained across the medium layer 58 in order to enable current to uniformly conduct across the medium layer 58. This is attributed to forming and maintaining filaments, or conducting channels, across the medium layer 58. However, forming and maintaining these conducting channels can be adversely influenced by the composition of the medium layer 58. For example, if the medium layer 58 is formed of a binary oxide or a complex oxide, its corresponding oxygen vacancies, if not sufficiently aligned and stabilized proximate to the conducting channels, can disrupt a low resistive state from being achieved. Consequently, the states of the memory device are less stable, resulting in data retention issues.

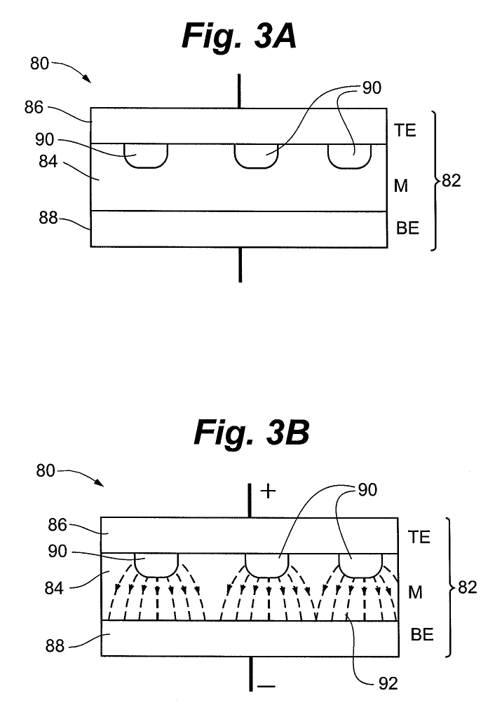

In addressing and overcoming the above issues as well as others described herein, a plurality of memory cell designs for RRAM devices that enable better writing and stability are shown in FIGS. 3-5.

FIGS. 3A and 3B depict elevation views of an exemplary memory cell in accordance with certain embodiments of the present invention. As shown, FIG. 3A shows a memory cell 80 forming a junction 82 that includes a medium layer 84 (referenced as M) sandwiched by two metallic electrodes, a first or top electrode 86 (referenced as TE) and a second or bottom electrode 88 (referenced as BE). In certain embodiments, with reference to FIGS. 1A and 1B, the memory cell 80 can be represented by any of the memory cells 14 and 14′, with their corresponding intersecting array conducting lines representing the top and bottom electrodes 86 and 88. “Top” and “Bottom” designations are used for clarity purposes only and should not be read to limit the invention.

Further provided in the memory cell 80 are metallic inclusions 90. As illustrated in FIG. 3A, in certain embodiments, the metallic inclusions 90 are one or more metallic islands in contact with one of the electrodes 86 or 88. In certain embodiments, the metallic inclusions 90 are formed directly onto the outer surface of the electrode 86 or 88. The metallic inclusions 90 can be formed onto the outer surface of the electrode 86 or 88 by any one of a number of processes, including sputtering, co-sputtering, evaporation, atomic layer deposition, and the like. In certain embodiments, the metallic inclusions 90 are arranged across the outer surface of the electrode 86 or 88 in the range of sub-10 nanometer scaling; however, the invention should not be limited to such, as the inclusions 90 can be just as well randomly located along the electrode 86 or 88. In certain embodiments, the metallic inclusions 90 are of uniform size on the outer surface of the electrode 86 or 88; however, the invention should not be limited to such, as the inclusions 90 can be just as well varied is size on the electrode 86 or 88. In certain embodiments, the metallic inclusions 90 are formed from the top electrode 86. However, the invention should not be so limited, as the metallic inclusions 88 could instead be formed from the bottom electrode 88, with the memory cell 80 functioning similarly.

In certain embodiments, the metallic inclusions 90 are the same metal materials as the electrodes 86 and 88; however, the invention should not be limited to such. Using the same materials for the metallic inclusions 90 and the electrodes from which it extends generally reduces the contact resistance between the metallic inclusions 90 and such electrode. However, in certain embodiments, the material for the metallic inclusions 90 is selected in order to optimize the interface between the inclusions 90 and the medium layer 84 for filament or conductive channel 92 formation (described below) or for oxygen vacancy retention, depending on the resistance switching mechanism (also described below).

As shown, in forming the metallic inclusions 90 on either the top electrode 86 or the bottom electrodes 88, the metallic inclusions 90 extend from the electrode into the medium layer 86. As such, it should be appreciated that the metallic inclusions 90 would correspondingly serve as electrically conductive additions to the electrodes 86 or 88. Consequently, the distance of the medium layer 84 between the electrodes 86 and 88 in areas where the metallic inclusions 90 extend from either of the electrodes 86, 88 would be significantly reduced. In certain preferred embodiments, the distance of the medium layer 84 in such areas may be reduced by between about 15 percent and about 40 percent, perhaps more preferable by between about 20 percent and about 35 percent, and perhaps optimally by between about 25 percent and 30 percent.

Accordingly, as shown in FIG. 3B, when an electrical pulse is delivered to the junction 82, filaments or conducting channels 92 form from the metallic inclusions 90 to the bottom electrode 88. As described above, the conducting channels 92 are formed through electrical fields which propagate from voltage being placed across the junction 82 of the memory cell 80. As should be appreciated, the strongest electrical fields are created along the paths of least resistance across the medium layer 84. These paths propagate between the metallic inclusions 90 and the bottom electrode 86. As a result, the conducting channels 92 are formed along these same paths, along which current passes from the metallic inclusions 90 to the bottom electrode 86.

As should be appreciated, the above-described effect of the metallic inclusions 90 on where the strongest electrical fields are created leads to these electrical fields being concentrated around the metallic inclusions 90. This leads to general confinement of the electrical fields stemming from the top electrode 86 in the areas of the metallic inclusions 90 and away from areas of the top electrode 86 between the metallic inclusions 90. Consequently, the conducting channels 92 are similarly formed in areas proximate to the metallic inclusions 90, extending out to the bottom electrode 88.

As described above, the metallic inclusions 90 sufficiently reduce the distance of the medium layer 84 between the electrodes 86 and 88 in areas where the metallic inclusions 90 extend from either of the electrodes 86, 88. Accordingly, and in light of the above, the extent of the conducting channels 92 is likewise reduced across the medium layer 84. As a result, each of the limitations (e.g., high write power, long write pulse duration, data retention and resistance variation challenges) that have been found to date with RRAM memory cells is addressed, as described below.

For example, because the electrical fields are concentrated proximate to the metallic inclusions 90, the writing power, and corresponding voltage level, for the EPIR effect can be reduced. By such concentration of the electrical fields, less power is needed to create the conducting channels 92 across the medium layer 84. In addition, because the metallic inclusions 90 reduce the distance of the medium layer 84 between the electrodes 86 and 88 in areas where the metallic inclusions 90 extend from either of the electrodes 86, 88, even less writing power is needed to create the conducting channels across this reduced distance. Accordingly, the writing power warranted is reduced in multiple ways.

In addition, because the electrical fields are concentrated proximate to the metallic inclusions 90, the conducting channels 92 generally do not extend across the entire length of the medium layer 84 to reach the bottom electrode 88. Accordingly, corresponding current flow is less likely to be undesirably delayed in flowing through the medium layer 84 between the metallic inclusions 90 and the bottom electrode 88. Also, because the metallic inclusions 90 reduce the distance of the medium layer 84 between the electrodes 86 and 88 in areas where the metallic inclusions 90 extend from either of the electrodes 86 or 88, there are fewer conducting paths the current could take in flowing from the metallic inclusions 90 extending from one of the electrodes 86 or 88, through the medium layer 58, to the other electrode. As a result, the duration for the average write pulse is reduced. Accordingly, the write pulse duration is reduced in multiple ways.

Further, as described above, because the electrical fields are concentrated proximate to the metallic inclusions 90, the conducting channels 92 generally do not extend across the entire length of the medium layer 84 to reach the bottom electrode 88. Accordingly, the property change in the junction 82 of the memory cell 80 is more easily confined. As such, the composition of the medium layer 84 has less impact on the conducting channels 92. Consequently, the states of the corresponding memory device are more stable, and data is therefore, more retainable. For example, in referenced to FIG. 3A, when the formation of the conducting channels 92 is the resistance switching mechanism for devices with binary oxides as the medium layer 84, the channels 92 are most likely formed and stabilized from the surfaces of the metallic inclusions 90 to the bottom electrode 88. Another example could involve the medium layer being formed of perovskite colossal magnetoresistive materials such as PrCaMnO₃. In such cases, the ferromagnetic nanoclusters can be aligned and stabilized by the concentrated electrical fields proximate to the metallic inclusions 90 to achieve a change in state, e.g., to low resistive state. Further, if the mobility of oxygen vacancies is the underlying resistance switching mechanism, the oxygen vacancies can be at or away from an interface between the metallic inclusions 90 and the medium layer 86, depending upon the voltage polarity. In all these examples, the write process is better controlled, leading to device stability and more retainable states. Similarly, the conductive channel is likely formed in the same location in different write cycles. Therefore, the resistance variation of the memory cell can be better controlled.

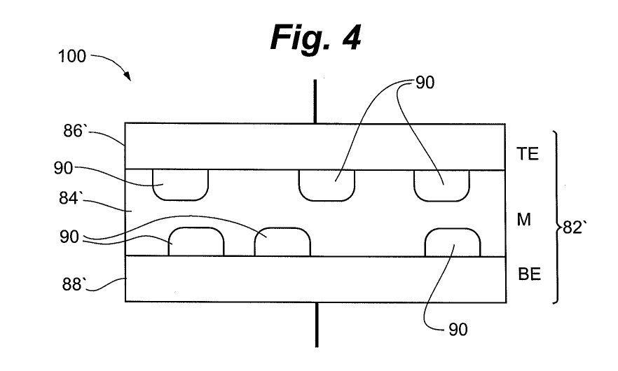

FIG. 4 depicts an elevation view of another exemplary memory cell in accordance with certain embodiments of the present invention. As shown, FIG. 4 shows a memory cell 100 forming a junction 82′ that includes a medium layer 84′ (referenced as M) sandwiched by two metallic electrodes, a top electrode 86 (referenced as TE) and a bottom electrode 88 (referenced as BE). In certain embodiments, with reference to FIGS. 1A and 1B, the memory cell 100 can be represented by any of the memory cells 14 and 14′, with their corresponding intersecting array conducting lines representing the top and bottom electrodes 86′ and 88′. Further provided in the memory cell 100 are metallic inclusions 90 provided on both the top and bottom electrodes 86′ and 88′, respectively.

As shown, in forming the metallic inclusions 90 on both the top electrode 86′ and the bottom electrodes 88′, the metallic inclusions 90 extend from both the electrodes 86′ and 88′ into the medium layer 86. As such, it should be appreciated that the metallic inclusions 90 would correspondingly serve as electrically conductive additions to both the electrodes 86′ or 88′. Consequently, the distance of the medium layer 84′ between the electrodes 86′ and 88′ in areas where the metallic inclusions 90 extend from the electrodes 86′, 88′ would be significantly reduced. In certain preferred embodiments, the distance of the medium layer 84′ in such areas may be reduced by between about 50 percent and about 75 percent, perhaps more preferable by between about 55 percent and about 70 percent, and perhaps optimally by between about 60 percent and 65 percent.

Accordingly, in light of the description with respect to the memory cell 80 of FIGS. 3A and 3B, when an electrical pulse is delivered to the junction 82′, filaments or conducting channels (not shown) generally form from the metallic inclusions 90 of the electrodes 86′ or 88′ toward the other electrode, depending on the polarity. As described above, the conducting channels are formed through electrical fields which propagate from voltage being placed across the junction 82′ of the memory cell 100. As should be appreciated, the strongest electrical fields are created along the paths of least resistance across the medium layer 84′. These paths could propagate between the metallic inclusions 90 of the top and bottom electrode 86′ and 88′. As a result, the conducting channels are formed along these same paths, along which current passes.

As should be appreciated, the above-described effect of the metallic inclusions 90 on where the strongest electrical fields are created leads to these electrical fields being concentrated around the metallic inclusions 90. This leads to general confinement of the electrical fields stemming from the electrodes 86′, 88′ in the areas of the metallic inclusions 90 and away from areas of the electrodes 86′, 88′ between the metallic inclusions 90. Consequently, the conducting channels are similarly formed in areas proximate to the metallic inclusions 90 from one of the electrodes 86′ or 88′, extending out to the other electrode.

As described above, the metallic inclusions 90 on both the top and bottom electrodes 86′ and 88′ sufficiently reduce the distance of the medium layer 84 between the electrodes 86′ and 88′ in areas where the metallic inclusions 90 extend from the electrodes 86′, 88′, even more so than in the memory cell 80 of FIGS. 3A and 3B. Accordingly, and in light of the above, the extents of the conducting channels are likewise reduced across the medium layer 84′. As a result, each of the limitations (e.g., high write power, long write pulse duration, and data retention challenges) that have been found to date with RRAM memory cells are further addressed, to an even larger degree, as compared to that already described above with respect to the memory cell 80 of FIGS. 3A and 3B.

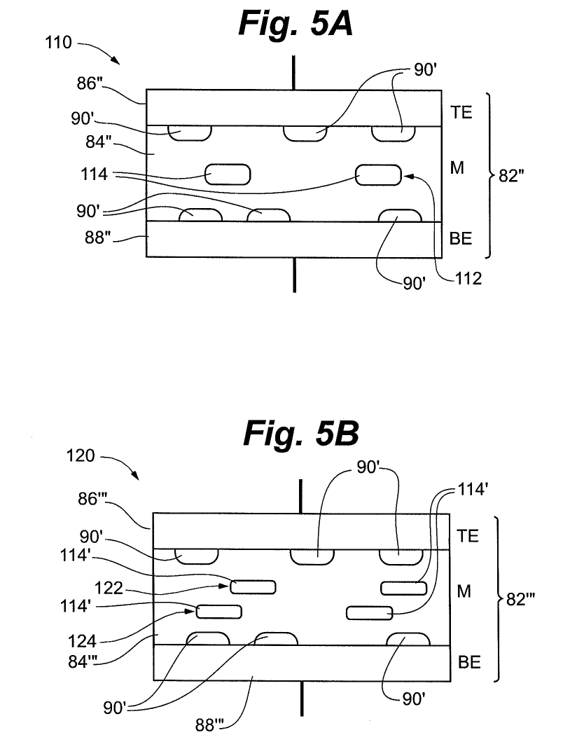

FIG. 5A and 5B depict elevation views of further exemplary memory cells in accordance with certain embodiments of the present invention. As shown, FIG. 5A shows a memory cell 110 forming a junction 82″ that includes a medium layer 84″ (referenced as M) sandwiched by two metallic electrodes, a top electrode 86″ (referenced as TE) and a bottom electrode 88″ (referenced as BE). In certain embodiments, with reference to FIGS. 1A and 1B, the memory cell 110 can be represented by any of the memory cells 14 and 14′, with their corresponding intersecting array conducting lines representing the top and bottom electrodes 86″ and 88″. Further provided in the memory cell 110 are metallic inclusions 90′ provided on both the top and bottom electrodes 86″ and 88″, respectively, along with a discontinuous layer 112 of metallic inclusions 114 in the bulk of the medium layer 84″. As shown, the bulk of the medium layer 84″ refers to the area of the medium layer 84″ that is between electrodes 86″, 88″ and/or between metallic inclusions 90′ adjacent electrodes 86″, 88″. As depicted, in certain embodiments, having a discontinuous layer 112 of metallic inclusions 114 in a bulk of the medium layer 84″ can warrant decreasing the size of the metallic inclusions 90′ extending from the electrodes 86″ and 88″ (as compared to the memory cell 80 of FIGS. 3A and 3B and the memory cell 100 of FIG. 4).

Similarly, FIG. 5B shows a memory cell 120 with similar construction to the memory cell 110 of FIG. 5A, except with multiple layers (e.g., first and second layers, 122 and 124, respectively) of metallic inclusions 114′ in the bulk of the medium layer 84′″. As depicted, in certain embodiments, having multiple discontinuous layers of metallic inclusions 114′ in a bulk of the medium layer 84′″ can warrant decreasing the size of both the metallic inclusions 90′ extending from the electrodes 86′″ and 88′″ (as compared to the memory cell 80 of FIGS. 3A and 3B and the memory cell 100 of FIG. 4) and the metal inclusions 114′ of the multiple discontinuous layers 122, 124 (as compared to the memory cell 110 of FIG. 5A). As shown, the bulk of the medium layer 84′″ refers to the area of the medium layer 84′″ that is between electrodes 86′″, 88′″ and/or between metallic inclusions 90′ adjacent electrodes 86′″, 88′″.

Based on the above description with respect to the memory cell 80 of FIGS. 3A and 3B and the memory cell 100 of FIG. 4, it should be appreciated that the memory cells 110 and 120 of FIGS. 5A and 5B, respectively, generate even stronger electrical fields across the medium layers 84′ and 84′″, respectively. This is based on the near continuity of the metallic inclusions 90′ and the metal inclusions 114 and metal inclusions 114′, of the memory cells 110 and 120 of FIGS. 5A and 5B, respectively, across the medium layers 84″ and 84′″, respectively, in comparison to the memory cell 80 of FIGS. 3A and 3B and the memory cell 100 of FIG. 4. Accordingly, and in light of the above, the extents of the conducting channels are likewise reduced across the medium layers 84″ and 84′″, respectively. As a result, each of the limitations (e.g., high write power, long write pulse duration, and data retention challenges) that have been found to date with RRAM memory cells are further addressed, to an even larger degree, with the memory cells 110 and 120 of FIGS. 5A and 5B as compared to that already described above with respect to the memory cell 80 of FIGS. 3A and 3B and the memory cell 100 of FIG. 4.

The medium layers 84, 84′, 84″, and 84′″ for the above embodied memory cells 80, 100, 110, and 120, respectively, are generally transition metal oxides, such as binary oxides. In certain embodiments, such binary metal oxides include CuO, MgO, NiO, CoO, ZnO, CrO₂, TiO₂, HfO₂, ZrO₂, Al₂O₃, Fe₂O₃, Nb₂O₅, and the like. Such medium layers, in certain embodiments, can alternatively be perovskite colossal magnetoresistive materials from the group of PrCaMnO₃, ferroelectric materials such as PbZrTiO₃, SrTiO₃, and SrTiO₃:Ru, and high-temperature superconducting materials such as GdCaBaCu₂O_{5+δ}, and the like. Such medium layers, in certain embodiments, can alternatively be organic or polymer materials that express the EPIR effect. In certain embodiments, the TE/M/BE junctions 82, 82′, 82″, and 82′″ for the above embodied memory cells 80, 100, 110, and 120, respectively, are symmetric, meaning that the material used for the electrodes 86 and 88, 86′ and 88′, 86″ and 88″, and 86′″ and 88′″, respectively, are the same. However, the invention should not be limited to such, as the junctions could just as well be asymmetric, or different. Materials for the electrodes can be metals including Pt, Cu, Au, Ag, Al, Ru, W, Ti, TiN, other like materials, and conductive metal oxides such as SrRuO₃.

Although the present invention has been described with reference to preferred embodiments, workers skilled in the art will recognize that changes may be made in form and detail without departing from the spirit and scope of the invention.

Thus, embodiments of the present invention are disclosed. Although the present invention has been described in considerable detail with reference to certain disclosed embodiments, the disclosed embodiments are presented for purposes of illustration and not limitation. The implementations described above and other implementations are within the scope of the following claims.

What is claimed is:

1. A nonvolatile memory cell comprising: a first electrode and a second electrode electrically connected by a medium layer, the medium layer formed of one or more of insulating material and semi-conductive material capable of switching resistance between at least two states, at least one of the first electrode and the second electrode having one or more metallic inclusions distributed thereon and extending therefrom into the medium layer.

2. The nonvolatile memory cell of claim 1 wherein the first electrode and second electrodes are formed of different materials.

3. The nonvolatile memory cell of claim 2 wherein the first electrode and the second electrode are formed of materials selected from the group consisting of Pt, Ag, Au, Ru, Cu, Al, W, Ti, TiN, and SrRuO₃.

4. The nonvolatile memory cell of claim 1 wherein the medium layer is formed of a binary metal oxide selected from the group consisting of CuO, MgO, NiO, CoO, ZnO, CrO₂, TiO₂, HfO₂, ZrO₂, Al₂O₃, Fe₂O₃, and Nb₂O₅.

5. The nonvolatile memory cell of claim 1 wherein the medium layer is formed of perovskite colossal magnetoresistive materials from the group of PrCaMnO₃.

6. The nonvolatile memory cell of claim 1 where the medium layer is formed of ferroelectric material selected from the group consisting of PbZrTiO₃, SrTiO₃, and SrTiO₃:Ru.

7. The nonvolatile memory cell of claim 1 wherein the first electrode and second electrode are formed of different materials than the one or more metallic inclusions.

8. The non-volatile memory cell of claim 1 wherein the one or more metallic inclusions are formed of a metal for optimizing interface between the one or more metallic inclusions and the medium layer for oxygen vacancy retention.

9. The non-volatile memory cell of claim 1 further comprising at least one layer of discontinuous metallic inclusions located in a bulk of the medium layer.

10. The non-volatile memory cell of claim 9 wherein the at least one layer of discontinuous metallic inclusions comprises two or more layers of discontinuous metallic inclusions.

11. The non-volatile memory cell of claim 1 wherein the one or more metal inclusions are formed on both the first electrode and second electrode.

12. The non-volatile memory cell of claim 1 wherein the metallic inclusions are of varying sizes and non-uniform locations on the at least one of the first electrode and the second electrode.

13. The non-volatile memory cell of claim 1 wherein the metallic inclusions enable concentration of electrical fields through the medium layer when the memory cell is energized.

14. A non-volatile memory array comprising:
a plurality of conductive array lines forming a first layer and a second layer, the array lines of the first layer crossing over the array lines of the second layer such that a plurality of cross points are formed between the array lines of the first layer and the array lines of the second layer; and
a layer of memory cells, each memory cell comprising a medium layer electrically connecting one of the array lines of the first layer with one of the array lines of the second layer at one of the cross points, the medium layer of each memory cell formed of one or more of insulating material and semi-conductive material capable of switching resistance between at least two states, one or both of the array lines of the first layer and the array lines of the second layer having one or more metallic inclusions distributed thereon and extending therefrom into the medium layers of the memory cells.

15. The non-volatile memory array of claim 14 wherein a select device such as a diode or transistor is connected with a memory cell in series at each cross point.

16. The non-volatile memory array of claim 14 wherein the medium layer of each of the memory cells further comprises at least one layer of discontinuous metallic inclusions located in a bulk of the medium layer.

17. The non-volatile memory array of claim 14 wherein the non-volatile memory array further comprises a second layer of memory cells stacked adjacent the plurality of conductive array lines forming a first layer and a plurality of conductive array lines forming a third layer stacked adjacent the second layer of memory cells.

18. The non-volatile memory array of claim 16 wherein the metallic inclusions and discontinuous metallic inclusions enable concentration of electrical fields through the medium layers when the memory cells are energized.

19. A nonvolatile memory cell comprising: an upper electrode and a lower electrode electrically connected by a medium layer, the medium layer formed of one or more of insulating material and semi-conductive material capable of switching resistance between at least two states, the upper electrode and the lower electrode each having one or more metallic inclusions distributed thereon and extending therefrom into the medium layer, the medium layer further comprising at least one layer of discontinuous metallic inclusions located in a bulk of the medium layer.

20. The nonvolatile memory cell of claim 19 wherein the metallic inclusions and discontinuous metallic inclusions enable concentration of electrical fields through the medium layer when the memory cell is energized.
